(19) United States
(12) Patent Application Publication
(10) Pub. No.: US 2026/0371824 A1
(43) Pub. Date: Nov. 19, 2026

(54) LIGHT-EMITTING DEVICE, DISPLAY DEVICE, AND ELECTRONIC APPARATUS

(71) Applicant: SEIKO EPSON CORPORATION, Tokyo (JP)

(72) Inventors: Koichiro AKASAKA, NAGANO-KEN,INA-SHI (JP); Yasuto AKATSUKA, NAGANO-KEN, CHINO-SHI (JP)

(73) Assignee: SEIKO EPSON CORPORATION, Tokyo (JP)

(21) Appl. No.: 18/613,143

(22) Filed: Mar. 22, 2024

(30) Foreign Application Priority Data
Mar. 24, 2023 (JP) 2023-047858

(51) Int. Cl. H10H 29/856

(52) U.S. Cl. CPC H10H 29/856

(57) ABSTRACT

A light-emitting device including a first electrode, a second electrode having a light-transmissive property, a first semiconductor layer provided between the first electrode and the second electrode and having a first conductivity type, a second semiconductor layer provided between the first semiconductor layer and the second electrode and having a second conductivity type different from the first conductivity type, a light-emitting layer provided between the first semiconductor layer and the second semiconductor layer, and a reflective layer provided between the first electrode and the first semiconductor layer and configured to reflect and condense light generated in the light-emitting layer toward the second electrode.

The present application is based on, and claims priority from JP Application Serial Number 2023-047858, filed Mar. 24, 2023, the disclosure of which is hereby incorporated by reference herein in its entirety.

### BACKGROUND

### 1. Technical Field

The present disclosure relates to a light-emitting device, a display device, and an electronic apparatus.

### 2. Related Art

A light-emitting device including a light-emitting element such as a light-emitting diode (LED) is applied as a light source of a display device or the like.

For example, WO 2021/246068 discloses a light-emitting device that includes a semiconductor layer configured by layering a first conductive layer, a light-emitting layer, and a second conductive layer each having a light-emitting surface in that order, includes a first electrode in contact with the second conductive layer and a second electrode in contact with the first conductive layer, and includes a plurality of light-emitting elements emitting light through the light-emitting surface from the light-emitting layer.

In the light-emitting device described above, it is desired to improve light extraction efficiency.

### SUMMARY

A light-emitting device according to one aspect of the present disclosure includes a first electrode, a second electrode having a light-transmissive property, a first semiconductor layer provided between the first electrode and the second electrode and having a first conductivity type, a second semiconductor layer provided between the first semiconductor layer and the second electrode and having a second conductivity type different from the first conductivity type, a light-emitting layer provided between the first semiconductor layer and the second semiconductor layer, and a reflective layer provided between the first electrode and the first semiconductor layer and configured to reflect and condense light generated in the light-emitting layer toward the second electrode.

A display device according to one aspect of the present disclosure includes the light-emitting device according to one aspect.

An electronic apparatus according to one aspect of the present disclosure includes the light-emitting device according to one aspect.

### BRIEF DESCRIPTION OF THE DRAWINGS

FIG. 1 is a cross-sectional view schematically illustrating a light-emitting device according to an embodiment.

FIG. 2 is a sectional view schematically illustrating a manufacturing step of the light-emitting device according to the present embodiment.

FIG. 3 is a cross-sectional view schematically illustrating a manufacturing step of the light-emitting device according to the present embodiment.

FIG. 4 is a cross-sectional view schematically illustrating a manufacturing step of the light-emitting device according to the present embodiment.

FIG. 5 is a cross-sectional view schematically illustrating a manufacturing step of the light-emitting device according to the present embodiment.

FIG. 6 is a cross-sectional view schematically illustrating a manufacturing step of the light-emitting device according to the present embodiment.

FIG. 7 is a cross-sectional view schematically illustrating a manufacturing step of the light-emitting device according to the present embodiment.

FIG. 8 is a cross-sectional view schematically illustrating a manufacturing step of the light-emitting device according to the present embodiment.

FIG. 9 is a cross-sectional view schematically illustrating a manufacturing step of the light-emitting device according to the present embodiment.

FIG. 10 is a cross-sectional view schematically illustrating a manufacturing step of the light-emitting device according to the present embodiment.

FIG. 11 is a cross-sectional view schematically illustrating a manufacturing step of the light-emitting device according to the present embodiment.

FIG. 12 is a cross-sectional view schematically illustrating a manufacturing step of the light-emitting device according to the present embodiment.

FIG. 13 is a cross-sectional view schematically illustrating a manufacturing step of the light-emitting device according to the present embodiment.

FIG. 14 is a cross-sectional view schematically illustrating a manufacturing step of the light-emitting device according to the present embodiment.

FIG. 15 is a cross-sectional view schematically illustrating a manufacturing step of the light-emitting device according to the present embodiment.

FIG. 16 is a cross-sectional view schematically illustrating a light-emitting device according to a first modification example of the present embodiment.

FIG. 17 is a cross-sectional view schematically illustrating a manufacturing step of the light-emitting device according to the first modification example of the present embodiment.

FIG. 18 is a cross-sectional view schematically illustrating a manufacturing step of the light-emitting device according to the first modification example of the present embodiment.

FIG. 19 is a sectional view schematically illustrating a light-emitting device according to a second modification example of the present embodiment.

FIG. 20 is a diagram schematically illustrating a projector according to the present embodiment.

FIG. 21 is a plan view schematically illustrating a display according to the present embodiment.

FIG. 22 is a cross-sectional view schematically illustrating the display according to the present embodiment.

FIG. 23 is a perspective view schematically illustrating a head-mounted display according to the present embodiment.

FIG. 24 is a diagram schematically illustrating an image forming device and a light-guiding device of the head-mounted display according to the present embodiment.

### DESCRIPTION OF EMBODIMENTS

Preferred embodiments of the present disclosure will be described in detail below with reference to the drawings. The embodiments described below do not unduly limit the content of the present disclosure described in the claims. In addition, not all the configurations described below are essential constituent elements of the present disclosure.

### 1. Light-emitting Device

### 1.1. Configuration

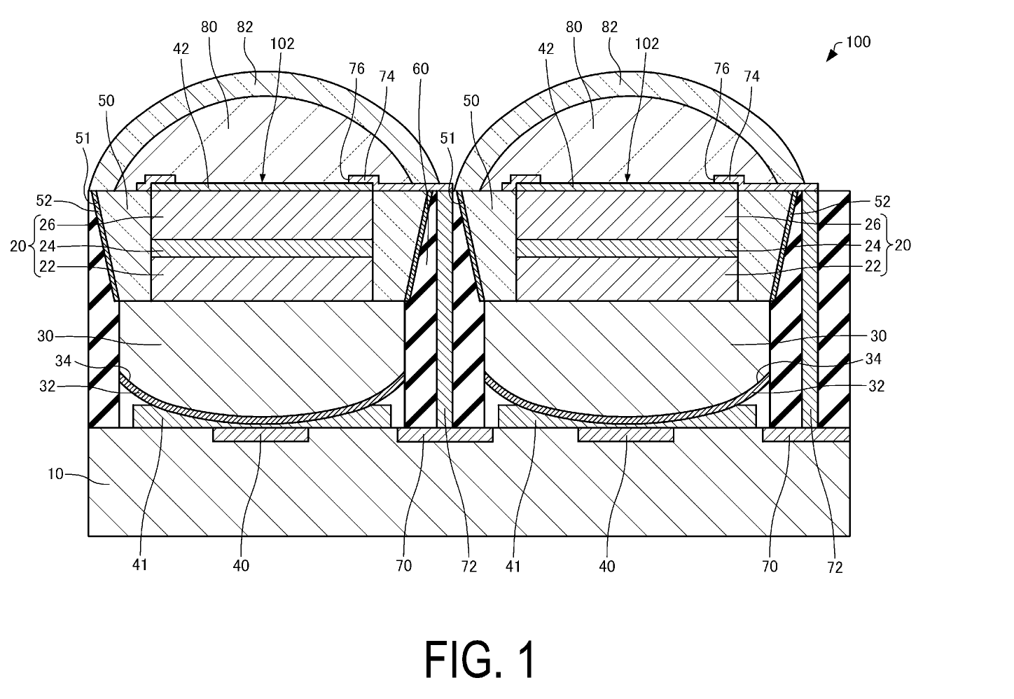

First, a light-emitting device according to the embodiment will be described with reference to the drawings. FIG. 1 is a cross-sectional view schematically illustrating a light-emitting device 100 according to the embodiment.

As illustrated in FIG. 1, the light-emitting device 100 includes a substrate 10, a layered body 20, a lens 30, a reflective layer 32, a first electrode 40, a second electrode 42, an insulating layer 50, a metal layer 52, an insulating layer 60, a pad 70, a plug 72, a wiring layer 74, a light-condensing unit 80, and a light-transmissive layer 82.

The substrate 10 is, for example, a silicon substrate.

The layered body 20 is separated from the substrate 10. The layered body 20 includes a first semiconductor layer 22, a light-emitting layer 24, and a second semiconductor layer 26. The first semiconductor layer 22, the light-emitting layer 24, and the second semiconductor layer 26 are, for example, a Group III nitride semiconductor and have a wurtzite crystal structure.

The first semiconductor layer 22 is provided on the lens 30. The first semiconductor layer 22 is provided between the first electrode 40 and the second electrode 42. The first semiconductor layer 22 has a first conductivity type. The first semiconductor layer 22 is, for example, an n-type GaN layer doped with Si.

In this specification, description is given on the assumption that a direction from the light-emitting layer 24 to the second semiconductor layer 26 is “upward” and a direction from the light-emitting layer 24 to the first semiconductor layer 22 is “downward” when the light-emitting layer 24 is used as a reference in a direction in which the first semiconductor layer 22 and the light-emitting layer 24 are layered (hereinafter also simply referred to as a “layering direction”). A direction perpendicular to the layering direction is also referred to as “lateral”.

The light-emitting layer 24 is provided on the first semiconductor layer 22. The light-emitting layer 24 is provided between the first semiconductor layer 22 and the second semiconductor layer 26. The light-emitting layer 24 has an i-type conductivity in which impurities are not intentionally doped. The light-emitting layer 24 generates light when a current is injected thereinto. The light-emitting layer 24 includes, for example, a well layer and a barrier layer. The well layer and the barrier layer are i-type semiconductor layers. The well layer is, for example, an InGaN layer. The barrier layer is, for example, a GaN layer. The light-emitting layer 24 has a multiple quantum well (MQW) structure constituted by the well layer and the barrier layer.

The number of well layers and the number of barrier layers constituting the light-emitting layer 24 are not particularly limited. For example, only one well layer may be provided, and in this case, the light-emitting layer 24 has a single quantum well (SQW) structure.

The second semiconductor layer 26 is provided on the light-emitting layer 24. The second semiconductor layer 26 is provided between the first semiconductor layer 22 and the second electrode 42. The second semiconductor layer 26 has a second conductivity type different from the first conductivity type. The second semiconductor layer 26 is, for example, a p-type GaN layer doped with Mg.

In the light-emitting device 100, a pin diode is constituted by the p-type second semiconductor layer 26, the i-type light-emitting layer 24, and the n-type first semiconductor layer 22. In the light-emitting device 100, when a forward bias voltage of the pin diode is applied between the first electrode 40 and the second electrode 42, a current is injected into the light-emitting layer 24, and electrons and holes are recombined in the light-emitting layer 24. The light-emitting layer 24 generates light by the recombination.

The lens 30 is provided below the layered body 20. The lens 30 is provided between the reflective layer 32 and the first semiconductor layer 22. The lens 30 is, for example, a convex lens. In the example illustrated in the drawing, the lower surface of the lens 30 is a convex surface. The lens 30 has a first conductivity type. The material of the lens 30 is, for example, n-type GaN doped with Si.

The reflective layer 32 is provided on the convex surface of the lens 30. The reflective layer 32 is provided between the first electrode 40 and the first semiconductor layer 22. A surface 34 of the reflective layer 32 on the first semiconductor layer 22 side is a concave surface. The surface 34 of the reflective layer 32 is in contact with the convex surface of the lens 30. The lens 30 may be in ohmic contact with the reflective layer 32. When viewed from the layering direction, for example, the light-emitting layer 24 is positioned inside the outer edge of the reflective layer 32. The reflective layer 32 is, for example, an Al layer. The reflective layer 32 reflects and condenses the light generated in the light-emitting layer 24 toward the second electrode 42. The reflective layer 32 may be a distributed bragg reflector (DBR) layer.

The first electrode 40 is provided on the substrate 10. The first electrode 40 is provided between the substrate 10 and the reflective layer 32. The material of the first electrode 40 is, for example, Al, Au, TiN, or the like. The first electrode 40 is bonded to the reflective layer 32 via, for example, a bonding member 41. The material of the bonding member 41 is, for example, gold-tin. The first electrode 40 is electrically coupled to the first semiconductor layer 22 via the bonding member 41, the reflective layer 32, and the lens 30. The first electrode 40 is one electrode for injecting a current into the light-emitting layer 24.

The second electrode 42 is provided on the second semiconductor layer 26. The second electrode 42 is provided between the second semiconductor layer 26 and the light-condensing unit 80. The second electrode 42 is electrically coupled to the second semiconductor layer 26. The second semiconductor layer 26 may be in ohmic contact with the second electrode 42. The second electrode 42 has a light-transmissive property. The second electrode 42 transmits light generated in the light-emitting layer 24. The material of the second electrode 42 is, for example, indium tin oxide (ITO). The second electrode 42 is the other electrode for injecting a current into the light-emitting layer 24.

The insulating layer 50 is provided on the lens 30. The insulating layer 50 is provided between the lens 30 and the light-condensing unit 80. The insulating layer 50 is provided on the side surface of the layered body 20. The insulating layer 50 surrounds the layered body 20 when viewed from the layering direction. The insulating layer 50 has a side surface 51. The side surface 51 is a side surface on a side opposite to the layered body 20. The side surface 51 is inclined with respect to the layering direction. The side surface 51 is inclined such that a distance between the side surface 51 and the layered body 20 increases from the lens 30 toward the light-condensing unit 80. The insulating layer 50 transmits light generated in the light-emitting layer 24. The insulating layer 50 is, for example, a silicon oxide layer or an aluminum oxide layer.

The metal layer 52 is provided on the side surface 51 of the insulating layer 50. The metal layer 52 is provided along the side surface 51. The metal layer 52 is provided at the side of the layered body 20 with the insulating layer 50 interposed therebetween. In the example illustrated in the drawing, the metal layer 52 is provided at the side of the first semiconductor layer 22, the light-emitting layer 24, and the second semiconductor layer 26. The metal layer 52 is, for example, an Al layer. The metal layer 52 reflects light generated in the light-emitting layer 24 toward the light-condensing unit 80.

The metal layer 52, the insulating layer 50, the electrodes 40 and 42, the reflective layer 32, the lens 30, and the layered body 20 constitute a light-emitting element 102. For example, a plurality of light-emitting elements 102 are provided. The plurality of light-emitting elements 102 may be arranged in a matrix when viewed in the layering direction. The light-emitting element 102 is, for example, an LED.

The insulating layer 60 is provided between adjacent light-emitting elements 102. The insulating layer 60 is provided at the sides of the metal layer 52 and the lens 30. The insulating layer 60 surrounds the layered body 20, the lens 30, the reflective layer 32, the insulating layer 50, and the metal layer 52 when viewed in the layering direction.

The pad 70 is provided on the substrate 10. The pad 70 is provided between the substrate 10 and the plug 72. The material of the pad 70 is, for example, the same as the material of the first electrode 40.

The plug 72 is provided in a contact hole in which the insulating layer 60 is formed. The plug 72 is provided between adjacent light-emitting elements 102. The plug 72 electrically couples the pad 70 and the wiring layer 74. The material of the plug 72 is, for example, tungsten.

The wiring layer 74 is provided on the plug 72, the insulating layers 50 and 60, and the second electrode 42. The wiring layer 74 electrically couples the plug 72 and the second electrode 42. The second electrode 42 is electrically coupled to the pad 70 via the wiring layer 74 and the plug 72. The wiring layer 74 is an Al layer, an Au layer, a Cu layer, or the like.

An opening portion 76 is formed in the wiring layer 74. The opening portion 76 extends through the wiring layer 74. The planar shape of the opening portion 76 may be circular. The opening portion 76 overlaps the light-emitting layer 24 when viewed from the layering direction. Light generated in the light-emitting layer 24 is emitted through the opening portion 76.

The light-condensing unit 80 is provided on the second electrode 42 and the wiring layer 74. The light-condensing unit 80 is provided on the side of the second electrode 42 opposite to the second semiconductor layer 26. In the example illustrated in the drawing, the light-condensing unit 80 is a convex lens. The upper surface of the light-condensing unit 80 is a convex surface. When viewed in the layering direction, the light-emitting layer 24 is located on the inner side of an outer edge of the light-condensing unit 80. The light-condensing unit 80 does not overlap the metal layer 52 when viewed in the layering direction. For example, a plurality of light-condensing units 80 are provided corresponding to the plurality of light-emitting elements 102. The material of the light-condensing unit 80 is, for example, silicon oxynitride. The light-condensing unit 80 condenses light generated in the light-emitting layer 24. The light-condensing unit 80 may be, for example, a reflective layer instead of the convex lens as long as the light-condensing unit 80 can condense light generated in the light-emitting layer 24.

The light-transmissive layer 82 is provided on the light-condensing unit 80. In the example illustrated in the drawing, the light-transmissive layer 82 is provided on the convex surface of the light-condensing unit 80. The refractive index of the light-transmissive layer 82 is, for example, lower than the refractive index of the light-condensing unit 80. Thereby, reflection at an interface between the light-condensing unit 80 and an air layer can be reduced. The material of the light-transmissive layer 82 is, for example, silicon oxide.

The refractive index of the light-transmissive layer 82 may be higher than the refractive index of the light-condensing unit 80. When the refractive index of the light-transmissive layer 82 is higher than the refractive index of the light-condensing unit 80, light generated in the light-emitting layer 24 can be further condensed. In this case, the material of the light-transmissive layer 82 is, for example, silicon nitride. Further, the light-transmissive layer 82 may not be provided.

Although the InGaN-based light-emitting layer 24 is described above, the light-emitting layer 24 can be made of various materials that can emit light when a current is injected thereinto, depending on the wavelength of emitted light. For example, semiconductor materials such as an AlGaN based, AlGaAs based, InGaAs based, InGaAsP based, InP based, GaP based, and AlGaP based materials can be used.

Although the description is given above on the assumption that the first conductivity type is an n-type and the second conductivity type is a p-type, the first conductivity type may be a p-type and the second conductivity type may be an n-type.

### 1.2. Operations and Effects

The light-emitting device 100 includes the first electrode 40, the second electrode 42 having a light-transmissive property, the first semiconductor layer 22 provided between the first electrode 40 and the second electrode 42 and having a first conductivity type, the second semiconductor layer 26 provided between the first semiconductor layer 22 and the second electrode 42 and having a second conductivity type different from the first conductivity type, the light-emitting layer 24 provided between the first semiconductor layer 22 and the second semiconductor layer 26, and the reflective layer 32 provided between the first electrode 40 and the first semiconductor layer 22 and configured to reflect and condense light generated in the light-emitting layer 24 toward the second electrode 42.

In this manner, in the light-emitting device 100, light generated in the light-emitting layer 24 is reflected and condensed toward the second electrode 42 by the reflective layer 32 provided between the first electrode 40 and the first semiconductor layer 22, and thus it is possible to reduce light coming out to the substrate 10 side. Thereby, light extraction efficiency can be improved. Furthermore, in the light-emitting device 100, light utilization efficiency can be improved.

In the light-emitting device 100, the surface 34 of the reflective layer 32 on the first semiconductor layer 22 side is a concave surface. For this reason, in the light-emitting device 100, light generated in the light-emitting layer 24 can be reflected and condensed toward the second electrode 42 by the surface 34 of the reflective layer 32.

The light-emitting device 100 includes the light-condensing unit 80 that is provided on the side of the second electrode 42 opposite to the second semiconductor layer 26 and condenses light generated in the light-emitting layer 24. For this reason, in the light-emitting device 100, it is possible to further improve light extraction efficiency as compared with when the light-condensing unit is not provided.

The light-emitting device 100 includes the metal layer 52 that is provided at the side of the light-emitting layer 24 and reflects light generated in the light-emitting layer 24 toward the light-condensing unit 80. For this reason, in the light-emitting device 100, light extraction efficiency can be further improved as compared with when the metal layer is not provided.

### 2. Method of Manufacturing Light-emitting Device

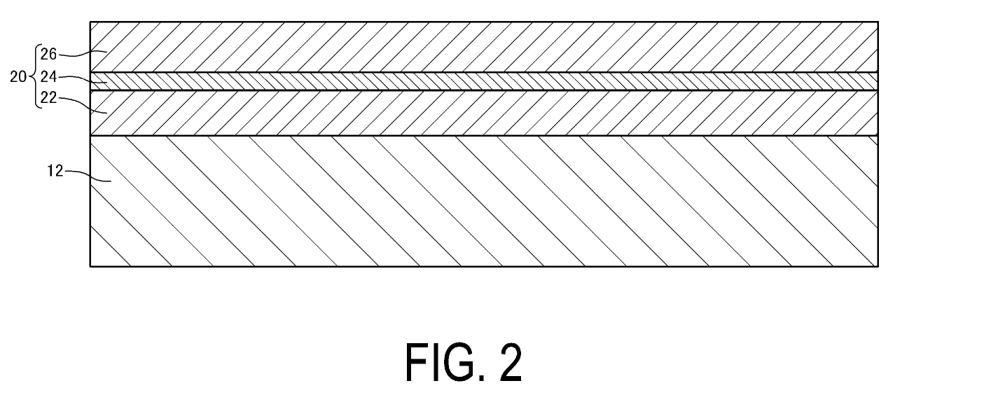

Next, a method of manufacturing the light-emitting device 100 according to the present embodiment will be described with reference to the drawings. FIGS. 2-15 are cross-sectional views schematically illustrating manufacturing steps of the light-emitting device 100 according to the present embodiment.

As illustrated in FIG. 2, the first semiconductor layer 22, the light-emitting layer 24, and the second semiconductor layer 26 are epitaxially grown on a growth substrate 12 in this order. Examples of the epitaxial growth method include a metal organic chemical vapor deposition (MOCVD) method and a molecular beam epitaxy (MBE) method. The growth substrate 12 is, for example, a GaN substrate.

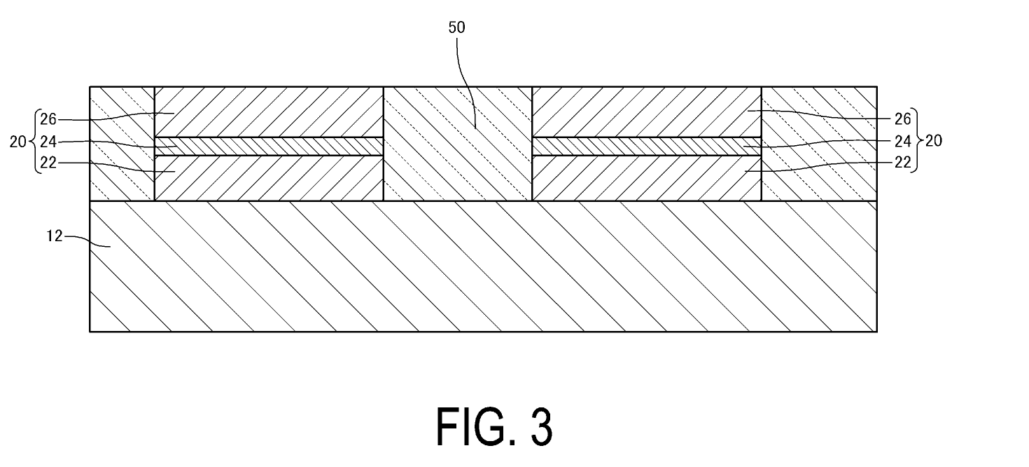

As illustrated in FIG. 3, the second semiconductor layer 26, the light-emitting layer 24, and the first semiconductor layer 22 are patterned to form the layered body 20. The patterning is performed by, for example, photolithography and etching.

Next, the insulating layer 50 is formed at the growth substrate 12 and at the side of the layered body 20. The insulating layer 50 is formed by, for example, a chemical vapor deposition (CVD) method, an atomic layer deposition (ALD) method, or a spin coating method.

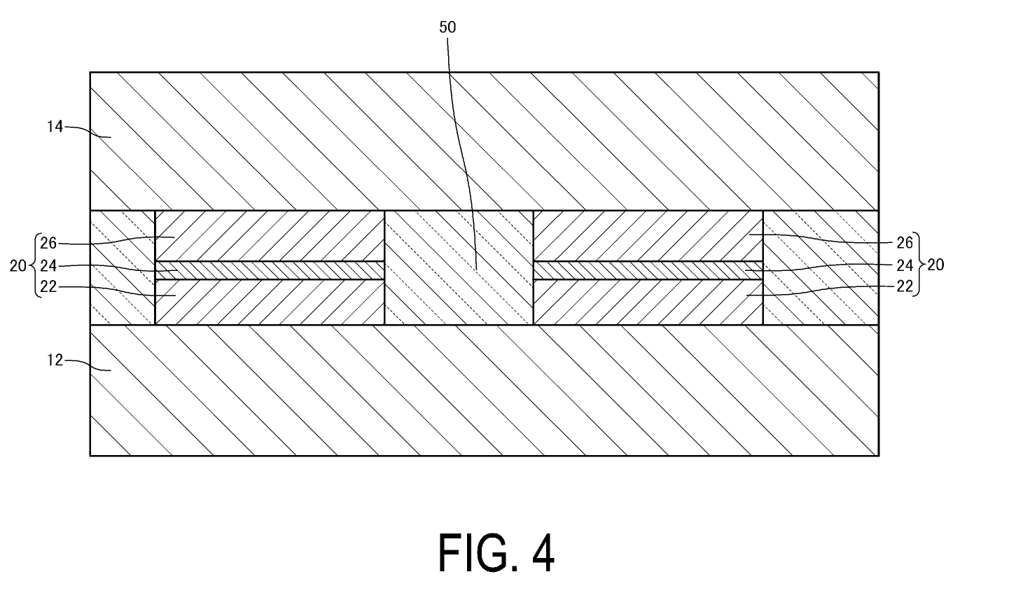

As illustrated in FIG. 4, a support substrate 14 is bonded to the layered body 20 and the insulating layer 50. The material of the support substrate 14 is not particularly limited as long as the support substrate 14 can support the layered body 20 and the insulating layer 50.

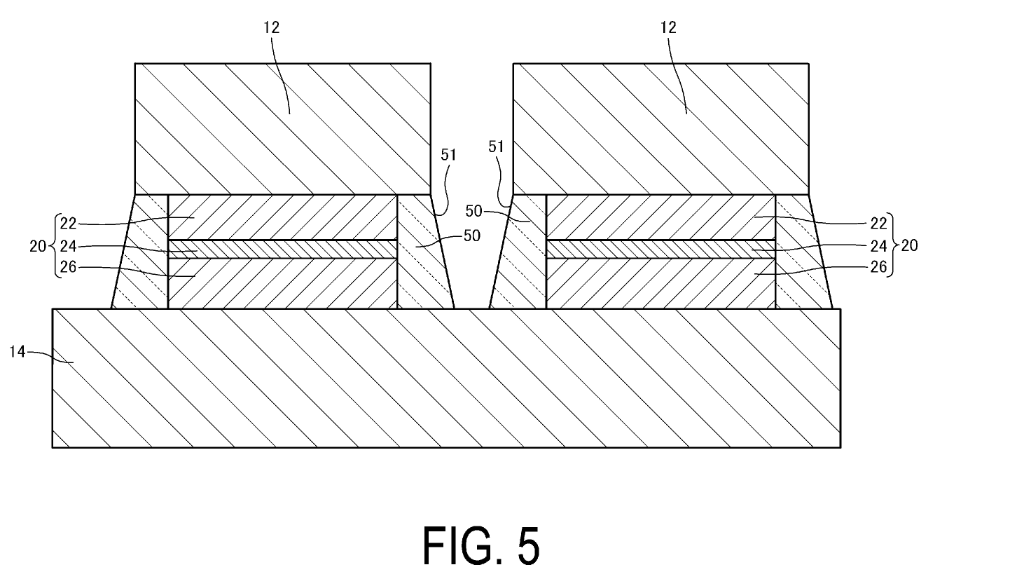

As illustrated in FIG. 5, a structure including the substrates 12 and 14, the layered body 20, and the insulating layer 50 is turned upside down from the state illustrated in FIG. 4. Then, the growth substrate 12 and the insulating layer 50 are patterned. The patterning is performed by, for example, photolithography and dry etching. The dry etching is performed such that the side surface 51 of the insulating layer 50 is inclined. Before the growth substrate 12 is patterned, the thickness of the growth substrate 12 may be reduced by etching or the like.

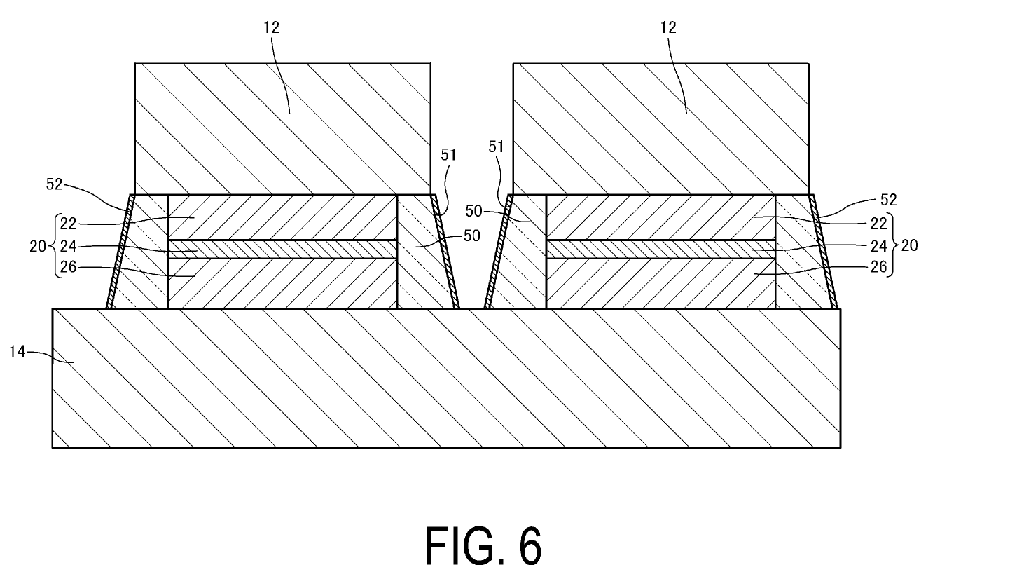

As illustrated in FIG. 6, the metal layer 52 is formed at the side surface 51 of the insulating layer 50. The metal layer 52 is formed by, for example, a vacuum deposition method.

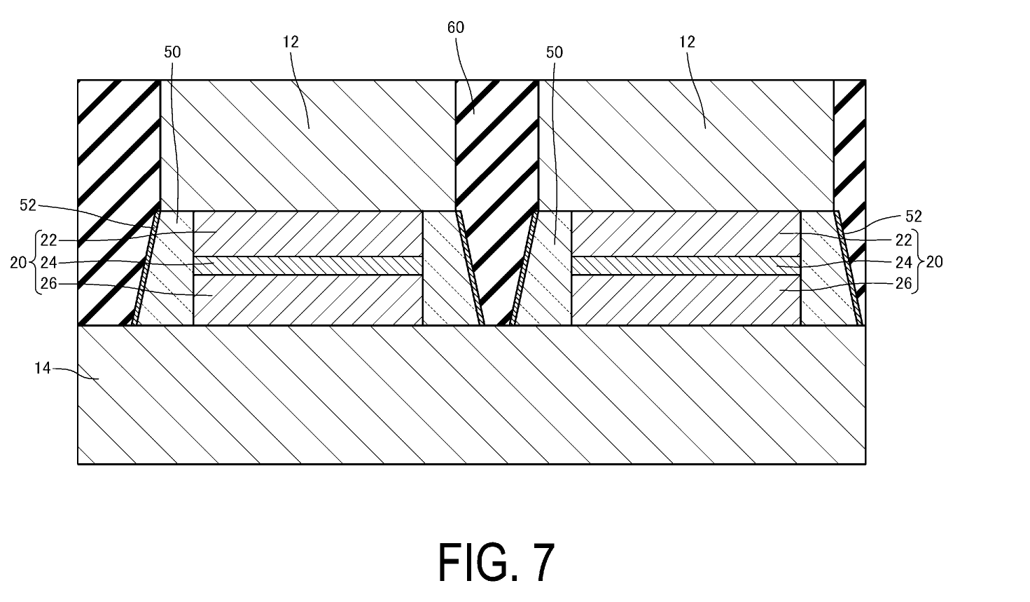

As illustrated in FIG. 7, the insulating layer 60 is formed covering the growth substrate 12. The insulating layer 60 is formed by, for example, a spin coating method. Next, the growth substrate 12 is exposed by removing a portion of the insulating layer 60. The insulating layer 60 is removed by, for example, etching or a chemical mechanical polisher (CMP).

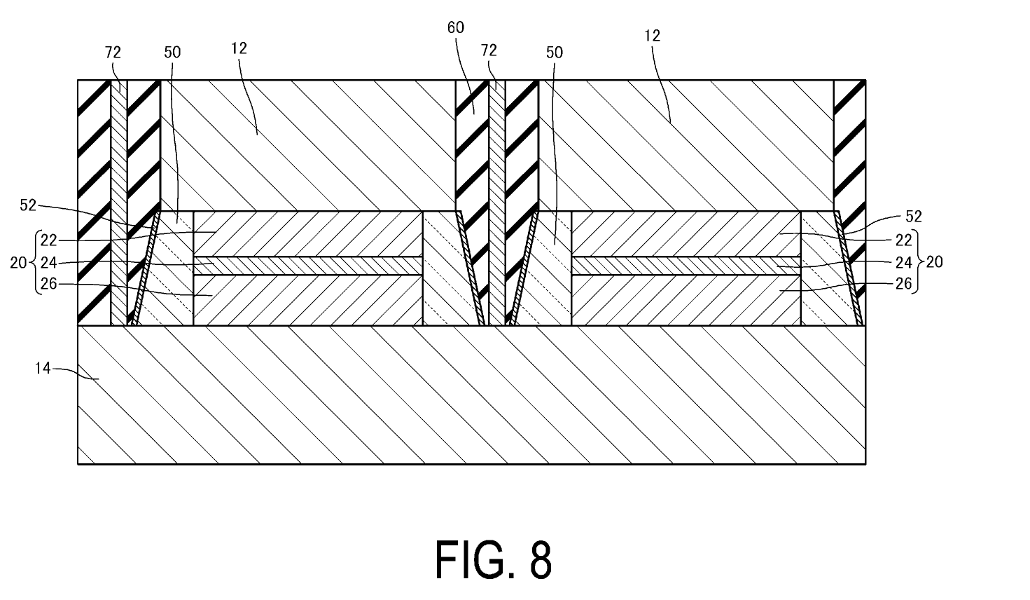

As illustrated in FIG. 8, the insulating layer 60 is patterned to form a contact hole, and the plug 72 is formed in the contact hole. The plug 72 is formed by, for example, a CVD method or a sputtering method.

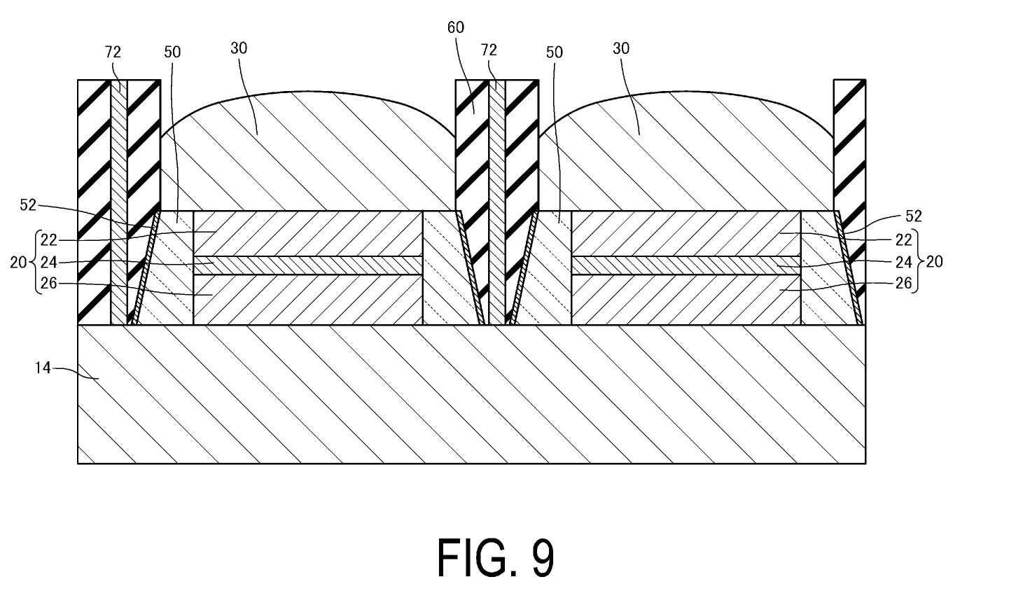

As illustrated in FIG. 9, the growth substrate 12 is patterned to form the lens 30. The patterning is performed by, for example, photolithography and dry etching. Specifically, a resist subjected to photolithography is heat-treated to smooth the corners of the resist. Thereafter, the growth substrate 12 is dry-etched using the resist as a mask, whereby the lens 30 having a convex surface can be formed.

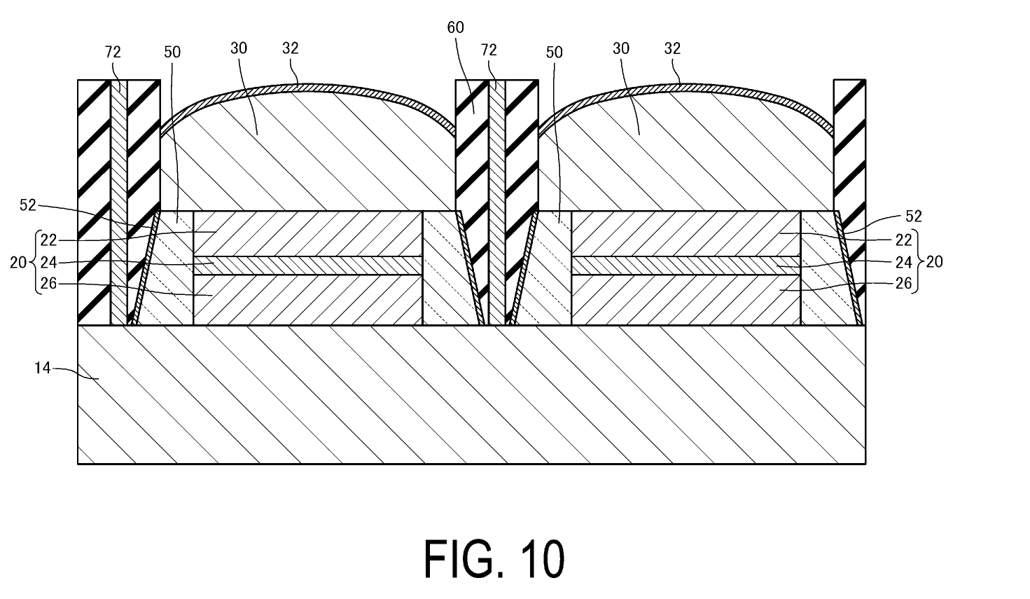

As illustrated in FIG. 10, the reflective layer 32 is formed at the convex surface of the lens 30. The reflective layer 32 is formed by, for example, a vacuum deposition method.

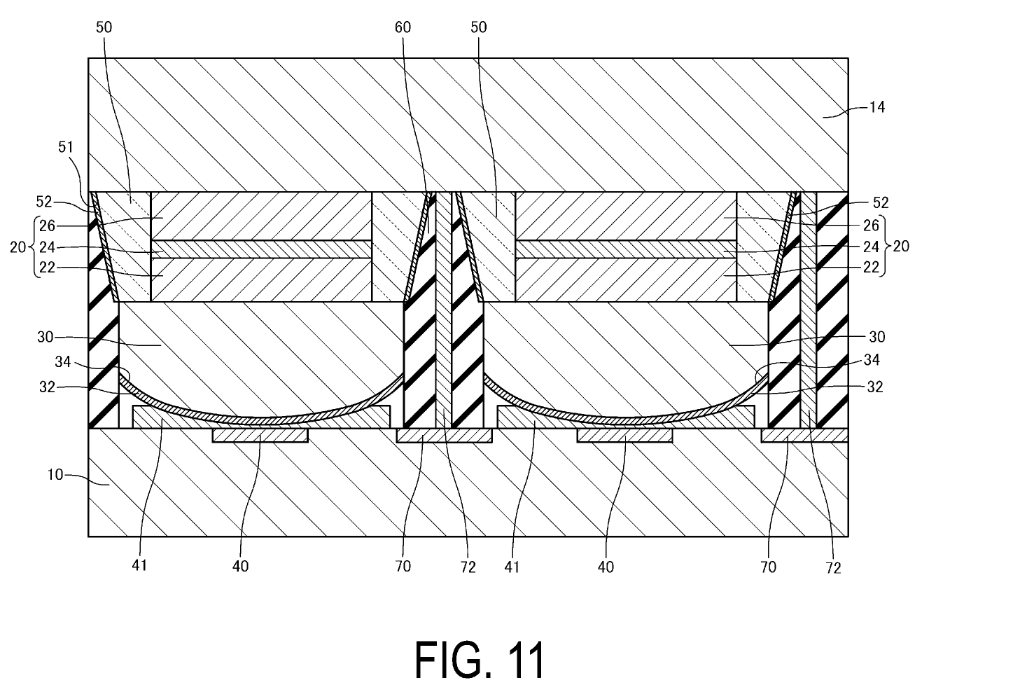

As illustrated in FIG. 11, a structure including the support substrate 14, the layered body 20, the lens 30, the reflective layer 32, the insulating layers 50 and 60, and the metal layer 52 is mounted on the substrate 10 on which the first electrode 40 and the pad 70 are formed. In the mounting, for example, the reflective layer 32 is bonded to the first electrode 40 via the bonding member 41, and the plug 72 is bonded to the pad 70 through metal-metal junction. The first electrode 40 and the pad 70 are formed by, for example, a vacuum evaporation method, a sputtering method, or a CVD method.

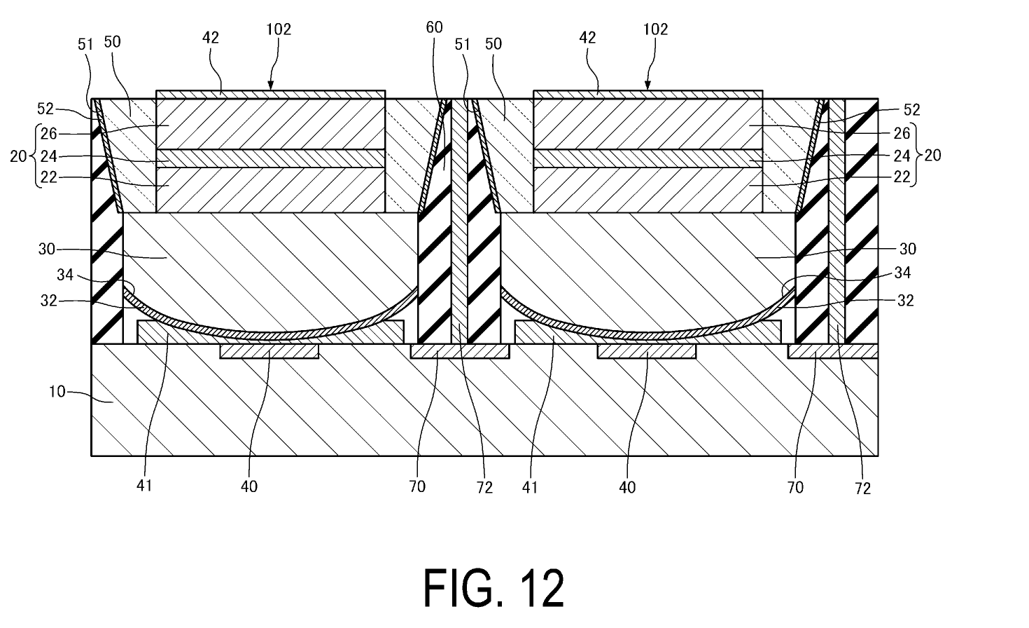

As illustrated in FIG. 12, the support substrate 14 is removed from the layered body 20. A method of removing the support substrate 14 is not particularly limited. Next, the second electrode 42 is formed at the second semiconductor layer 26. The second electrode 42 is formed by, for example, a vacuum deposition method, a sputtering method, or a CVD method. The light-emitting element 102 is formed through this step.

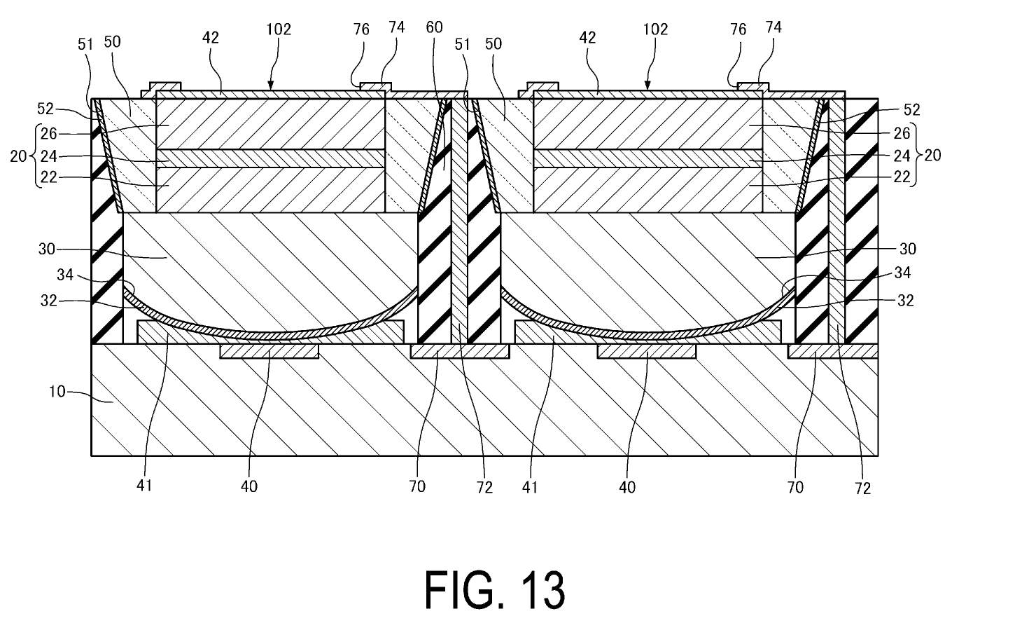

As illustrated in FIG. 13, the wiring layer 74 is formed at the second electrode 42, the insulating layers 50 and 60, and the plug 72. The wiring layer 74 is formed by, for example, a vacuum evaporation method, a sputtering method, or a CVD method.

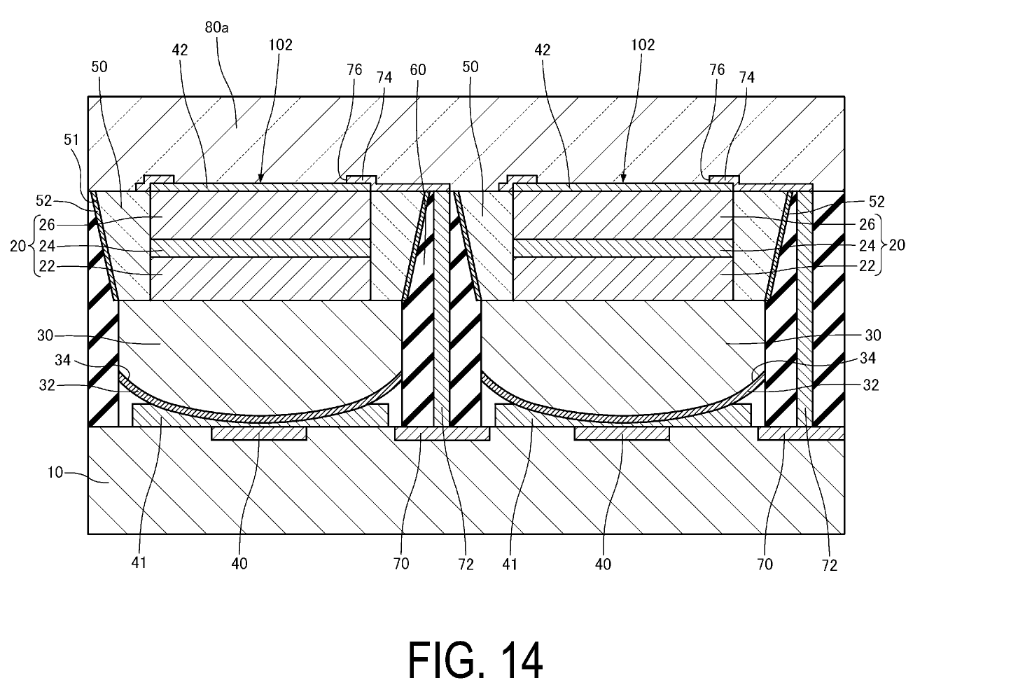

As illustrated in FIG. 14, a light-transmissive layer 80a serving as the light-condensing unit 80 is formed at the second electrode 42. The light-transmissive layer 80a is formed by, for example, a CVD method or an ALD method.

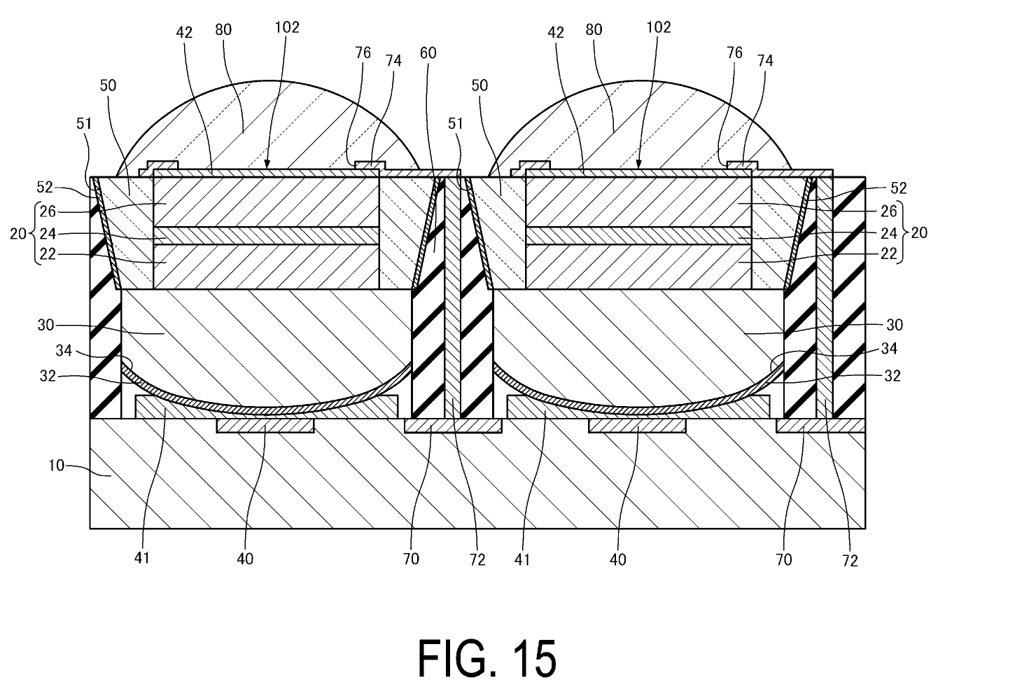

As illustrated in FIG. 15, the light-transmissive layer 80a is patterned to form the light-condensing unit 80. The patterning is performed, for example, in the same manner as the patterning for forming the lens 30 described above.

As illustrated in FIG. 1, the light-transmissive layer 82 is formed at the light-condensing unit 80. The light-transmissive layer 82 is formed by, for example, a CVD method or an ALD method.

The light-emitting device 100 can be manufactured through the above-described steps.

### 3. Modification Example of Light-emitting Device

### 3.1. First Modification Example

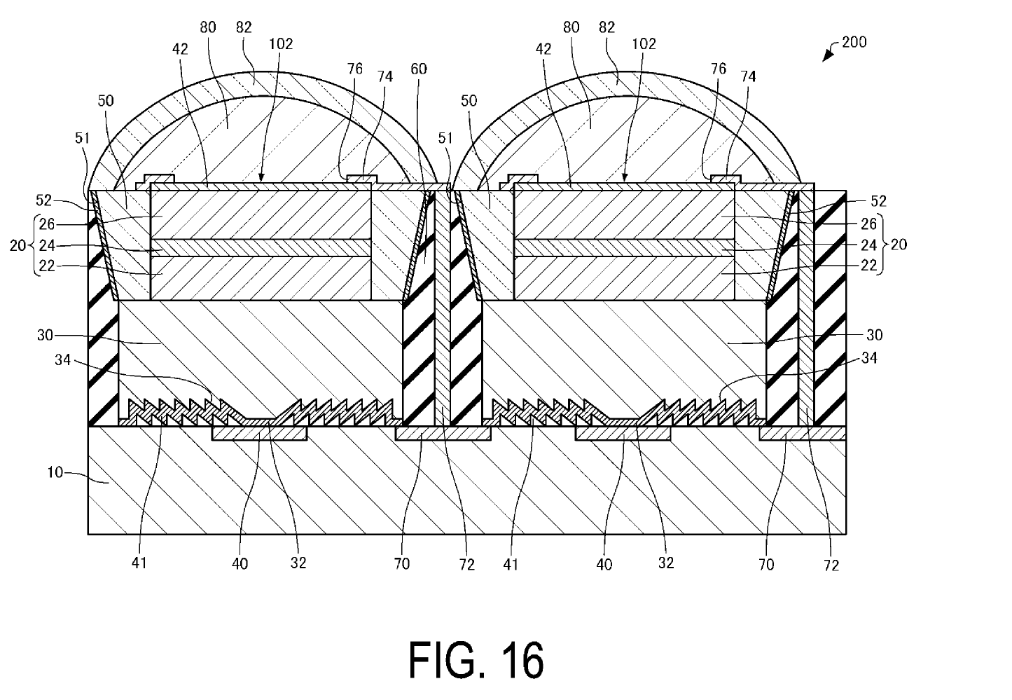

Next, a light-emitting device according to a first modification example of the present embodiment will be described with reference to the drawings. FIG. 16 is a cross-sectional view schematically illustrating a light-emitting device 200 according to the first modification example of the present embodiment.

In the following description, in the light-emitting device 200 according to the first modification example of the present embodiment, members having the same functions as the constituent members of the light-emitting device 100 according to the present embodiment described above will be denoted by the same reference signs, and detailed description thereof will be omitted. The same applies to a light-emitting device according to a second modification example of the present embodiment, which will be described later.

In the light-emitting device 100 described above, the lens 30 is a convex lens as illustrated in FIG. 1.

On the other hand, in the light-emitting device 200, the lens 30 is a Fresnel lens as illustrated in FIG. 16. A lens 30 has a saw shape. Sawtooth blades of the lens 30 are provided, for example, periodically. A reflective layer 32 is provided on a saw-shaped surface of the lens 30. The reflective layer 32 is bonded to the first electrode 40, for example, through metal-metal junction. Although not illustrated in the drawing, the reflective layer 32 may be bonded to the first electrode 40 via a bonding member made of gold-tin or the like.

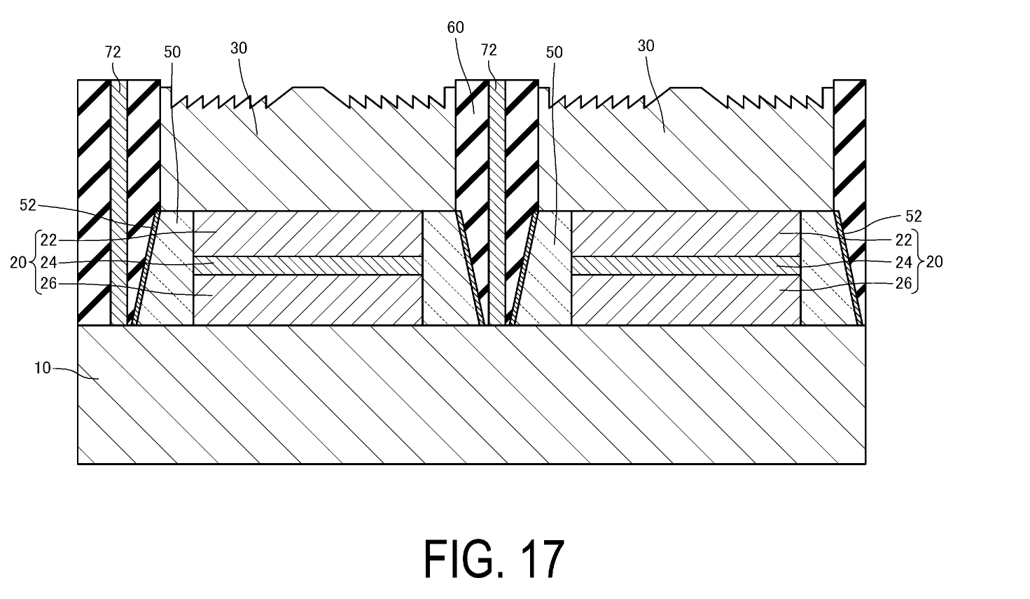

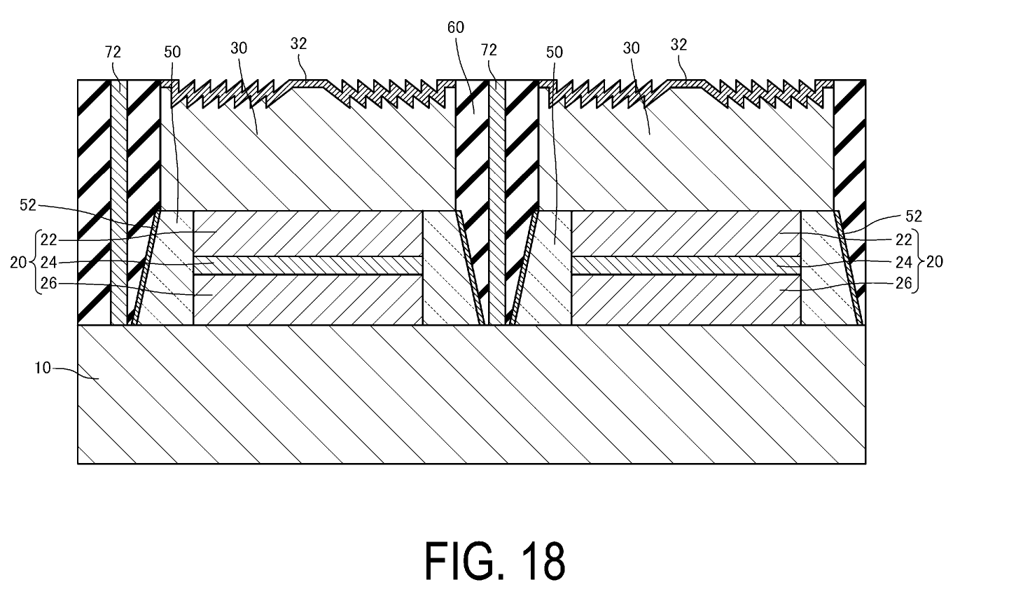

In a method of manufacturing the light-emitting device 200, after a plug 72 is formed as illustrated in FIG. 8, the lens 30 is formed by patterning a growth substrate 12 in a saw shape as illustrated in FIG. 17. The patterning is performed by, for example, photolithography and dry etching. Thereafter, as illustrated in FIG. 18, the reflective layer 32 is formed at the saw-shaped surface of the lens 30. The subsequent steps are basically the same as those of the method of manufacturing the light-emitting device 100 described above. FIGS. 17 and 18 are cross-sectional views schematically illustrating manufacturing steps of the light-emitting device 200.

In the light-emitting device 200, the lens 30 is a Fresnel lens. For this reason, in the light-emitting device 200, a processing time for the lens 30 can be shortened as compared with when a convex lens is used. When a Fresnel lens is formed, a growth substrate 12 may not be etched deeply as compared with when a convex lens is formed, and thus an etching time can be shortened.

### 3.2. Second Modification Example

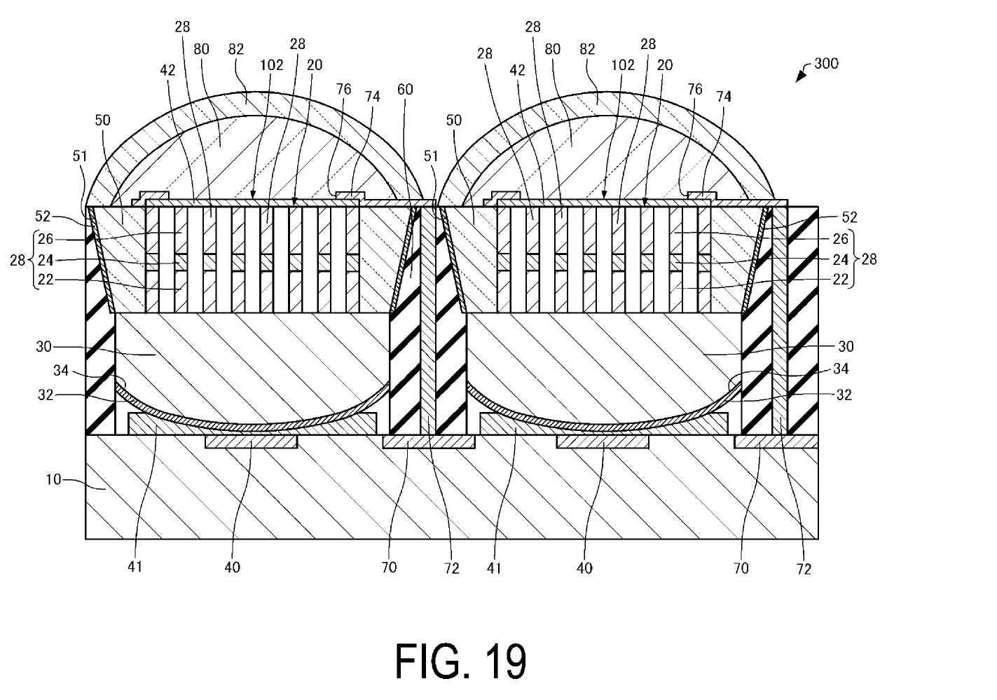

Next, a light-emitting device according to a second modification example of the present embodiment will be described with reference to the drawings. FIG. 19 is a cross-sectional view schematically illustrating a light-emitting device 300 according to the second modification example of the present embodiment.

The light-emitting device 300 differs from the light-emitting device 100 described above in that a first semiconductor layer 22, a light-emitting layer 24, and a second semiconductor layer 26 constitute a plurality of columnar portions 28, as illustrated in FIG. 19. A layered body 20 has the plurality of columnar portions 28.

The columnar portion 28 is provided on a lens 30. The columnar portion 28 protrudes upward from the lens 30. The columnar portion 28 is also referred to as, for example, a nanocolumn, a nanowire, a nanorod, or a nanopillar. The planar shape of the columnar portion 28 is, for example, a polygon such as a regular hexagon, or a circle.

The diameter of the columnar portion 28 is, for example, 50 nm or more and 500 nm or less. By setting the diameter of the columnar portions 28 to 500 nm or less, it is possible to obtain a high-quality crystal light-emitting layer 24 and reduce distortion inherent in the light-emitting layer 24.

The “diameter of the columnar portion 28” is a diameter when the planar shape of the columnar portion 28 is a circle, and is the diameter of a minimum inclusion circle when the planar shape of the columnar portion 28 is not a circle. For example, when the planar shape of the columnar portion 28 is a polygon, the diameter of the columnar portion 28 is the diameter of a smallest circle that includes the polygon therein, and when the planar shape of the columnar portion 28 is an ellipse, the diameter of the columnar portion 28 is the diameter of a smallest circle that includes the ellipse therein.

The plurality of columnar portions 28 are spaced apart from each other. In the example illustrated in the drawing, there is a gap between adjacent columnar portions 28. An interval between the adjacent columnar portions 28 is, for example, 1 nm or more and 500 nm or less. The plurality of columnar portions 28 are arranged in a predetermined direction at a predetermined pitch when viewed from the layering direction. The plurality of columnar portions 28 are arranged in, for example, a regular triangular lattice shape or a square lattice shape. The plurality of columnar portions 28 can exhibit the effect of a photonic crystal.

The “pitch of the columnar portions 28” is a distance between the centers of the columnar portions 28 adjacent to each other in a predetermined direction. When the planar shape of the columnar portion 28 is a circle, the “center of the columnar portion 28” is the center of the circle, and when the planar shape of the columnar portion 28 is not a circle, the “center of the columnar portion 28” is the center of a minimum inclusion circle. For example, when the planar shape of the columnar portion 28 is a polygon, the center of the columnar portion 28 is the center of the smallest circle that includes the polygon therein, and when the planar shape of the columnar portion 28 is an ellipse, the center of the columnar portion 28 is the center of the smallest circle that includes the ellipse therein.

In the light-emitting device 300, the first semiconductor layer 22, the light-emitting layer 24, and the second semiconductor layer 26 constitute a plurality of columnar portions 28. For this reason, in the light-emitting device 300, the distortion of the light-emitting layer 24 can be reduced. Furthermore, a light-emitting element 102 of the light-emitting device 300 may be a semiconductor laser, and in this case, light generated in the light-emitting layer 24 can be laser-oscillated by the effect of the photonic crystal formed by the plurality of columnar portions 28. Then, +1st-order diffracted light and -1st-order diffracted light can be emitted as laser beams in the layering direction.

### 4. Projector

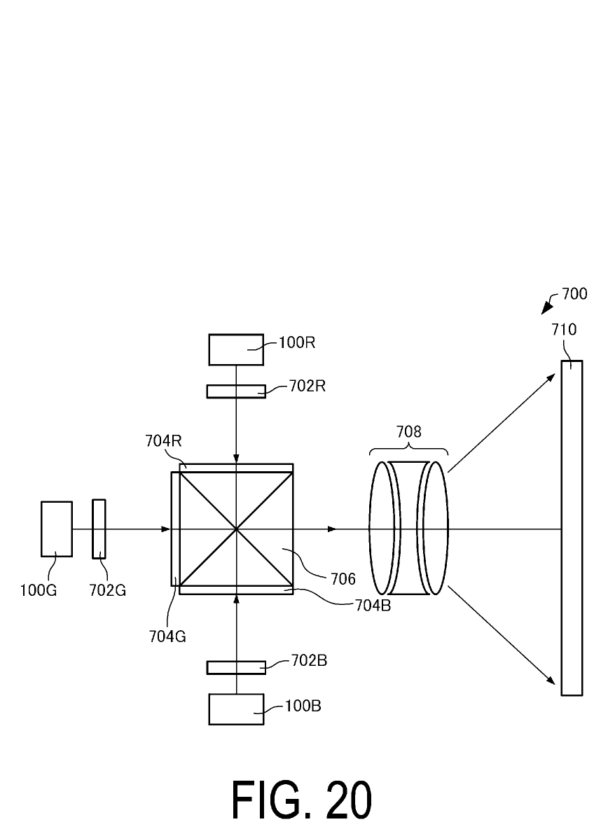

Next, a projector as a display device according to the present embodiment will be described with reference to the drawings. FIG. 20 is a plan view schematically illustrating a projector 700 according to the present embodiment.

The projector 700 includes, for example, the light-emitting device 100 as a light source.

The projector 700 includes a housing, which is not illustrated in the drawing, and a red light source 100R, a green light source 100G, and a blue light source 100B that are provided in the housing and emit red light, green light, and blue light, respectively. For the sake of convenience, the red light source 100R, the green light source 100G, and the blue light source 100B are illustrated in FIG. 20 in a simplified manner.

The projector 700 further includes a first optical element 702R, a second optical element 702G, a third optical element 702B, a first optical modulation device 704R, a second optical modulation device 704G, a third optical modulation device 704B, and a projection device 708 which are provided in the housing. The first optical modulation device 704R, the second optical modulation device 704G, and the third optical modulation device 704B are, for example, transmissive liquid crystal light valves. The projection device 708 is, for example, a projection lens.

The light emitted from the red light source 100R is incident on the first optical element 702R. The light emitted from the red light source 100R is condensed by the first optical element 702R. The first optical element 702R may have a function other than that of condensing light. The second optical element 702G and the third optical element 702B may also have a function other than that of condensing light.

The light condensed by the first optical element 702R is incident on the first optical modulation device 704R. The first optical modulation device 704R modulates the incident light based on image information. Then, the projection device 708 enlarges an image formed by the first optical modulation device 704R and projects the image on a screen 710.

The light emitted from the green light source 100G is incident on the second optical element 702G. The light emitted from the green light source 100G is condensed by the second optical element 702G.

The light condensed by the second optical element 702G is incident on the second optical modulation device 704G. The second optical modulation device 704G modulates the incident light based on image information. Then, the projection device 708 enlarges an image formed by the second optical modulation device 704G and projects the image on the screen 710.

The light emitted from the blue light source 100B is incident on the third optical element 702B. The light emitted from the blue light source 100B is condensed by the third optical element 702B.

The light condensed by the third optical element 702B is incident on the third optical modulation device 704B. The third optical modulation device 704B modulates the incident light based on image information. Then, the projection device 708 enlarges the image formed by the third optical modulation device 704B and projects the image on the screen 710.

The projector 700 further includes a cross dichroic prism 706 that synthesizes the light emitted from the first optical modulation device 704R, the light emitted from the second optical modulation device 704G, and the light emitted from the third optical modulation device 704B and guides the synthesized light to the projection device 708.

Light beams of three colors modulated by the first optical modulation device 704R, the second optical modulation device 704G, and the third optical modulation device 704B are incident on the cross dichroic prism 706. In the cross dichroic prism 706, four right-angle prisms are bonded together, and a dielectric multilayer film that reflects red light and a dielectric multilayer film that reflects blue light are disposed on inner surfaces of the prisms. The light beams of three colors are synthesized by the dielectric multilayer films, and light representing a color image is formed. Then, the synthesized light is projected onto the screen 710 by the projection device 708, and an enlarged image is displayed.

The red light source 100R, the green light source 100G, and the blue light source 100B control the light-emitting devices 100 as pixels of a video based on image information, and thus the video may be directly formed without using the first optical modulation device 704R, the second optical modulation device 704G, and the third optical modulation device 704B. The projection device 708 may project the video formed by the red light source 100R, the green light source 100G, and the blue light source 100B onto the screen 710 in an enlarged manner. In this case, the red light source 100R, the green light source 100G, and the blue light source 100B are disposed to face the three incident surfaces of the cross dichroic prism 706, respectively. Image light beams respectively emitted from the red light source 100R, the green light source 100G, and the blue light source 100B are incident on the three incident surfaces of the cross dichroic prism 706 and are synthesized in the cross dichroic prism 706.

Although the transmissive liquid crystal light valve is used as the optical modulation device in the above-described example, a light valve other than the liquid crystal light valve may be used, or a reflective light valve may be used. Examples of such a light valve include a reflective liquid crystal light valve and a digital micro mirror device. A configuration of the projection device is changed as appropriate depending on the type of light valve to be used.

The light source can also be applied to a light source device of a scanning type image display device including a scanning unit which is an image forming device for displaying an image having a desired size on a display surface by scanning a screen with light emitted from the light source.

### 5. Display

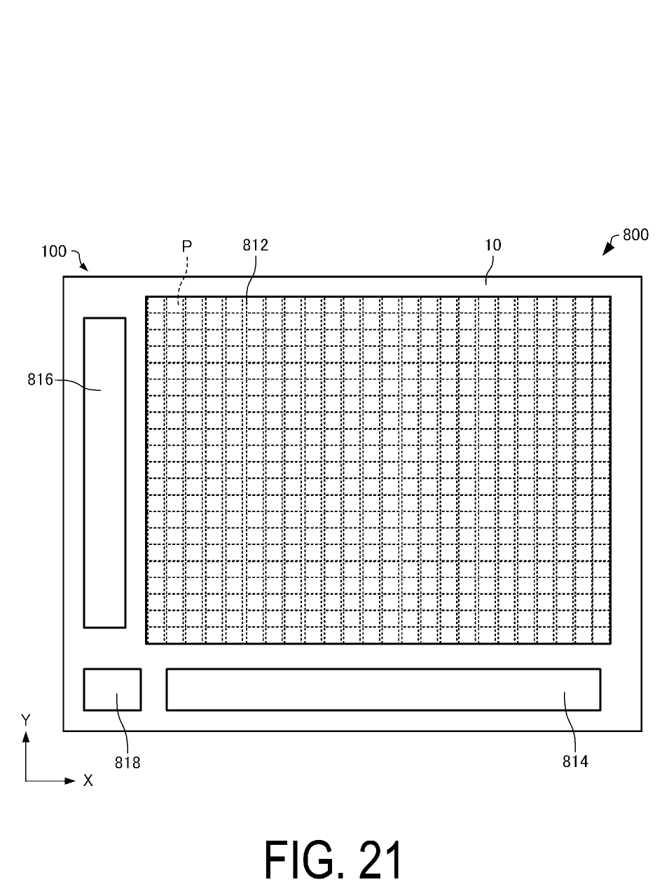

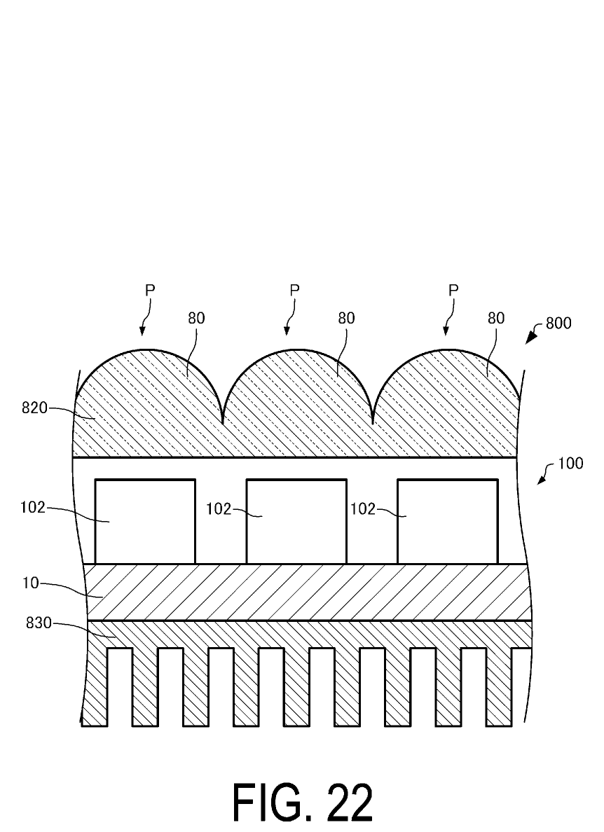

Next, a display as a display device according to the present embodiment will be described with reference to the drawings. FIG. 21 is a plan view schematically illustrating a display 800 according to the present embodiment. FIG. 22 is a cross-sectional view schematically illustrating the display 800 according to the present embodiment. An X-axis and a Y-axis are illustrated in FIG. 21 as two axes orthogonal to each other.

The display 800 includes, for example, the light-emitting device 100 as a light source. For the sake of convenience, the light-emitting device 100 is illustrated in FIGS. 21 and 22 in a simplified manner.

The display 800 is a display device that displays an image. The image includes those only displaying character information. The display 800 is a self-luminous display. As illustrated in FIGS. 21 and 22, the display 800 includes, for example, a lens array 820 and a heat sink 830.

A driving circuit for driving the light-emitting element 102 of the light-emitting device 100 is mounted on the substrate 10. The driving circuit is a circuit including, for example, a complementary metal oxide semiconductor (CMOS) and the like. The driving circuit drives the light-emitting element 102 based on, for example, input image information.

The substrate 10 includes, for example, a display region 812, a data line driving circuit 814, a scanning line driving circuit 816, and a control circuit 818.

The display region 812 is constituted by a plurality of pixels P. In the example illustrated in the drawing, the pixels P are arranged along the X-axis and the Y-axis.

Although not illustrated in the drawing, the substrate 10 is provided with a plurality of scanning lines and a plurality of data lines. For example, the scanning lines extend along the X-axis and the data lines extend along the Y-axis. The scanning lines are coupled to the scanning line driving circuit 816. The data lines are coupled to the data line driving circuit 814. The pixels P are provided corresponding to intersections between the scanning lines and the data lines.

One pixel P includes, for example, one light-emitting element 102, one light-condensing unit 80, and a pixel circuit (not illustrated). The pixel circuit includes a switching transistor that serves as a switch for the pixel P, a gate of the switching transistor is coupled to the scanning line, and one of a source and a drain thereof is coupled to the data line.

The data line driving circuit 814 and the scanning line driving circuit 816 are circuits that control driving of the light-emitting device 100 constituting the pixel P. The control circuit 818 controls display of an image.

Image data is supplied to the control circuit 818 from an upper level circuit. The control circuit 818 supplies various signals based on the image data to the data line driving circuit 814 and the scanning line driving circuit 816.

When the scanning line is selected by activating the scanning signal by the scanning line driving circuit 816, the switching transistor provided in the selected pixel P is turned on. At this time, the data line driving circuit 814 supplies a data signal from the data line to the selected pixel P, and thus the light-emitting device 100 of the selected pixel P emits light based on the data signal.

The lens array 820 is constituted by a plurality of light-condensing units 80. For example, one light-condensing unit 80 is provided for one light-emitting element 102.

The heat sink 830 is in contact with the substrate 10. The material of the heat sink 830 is, for example, a metal such as copper or aluminum. The heat sink 830 radiates heat generated by the light-emitting element 102.

### 6. Head-mounted Display

### 6.1. Overall Configuration

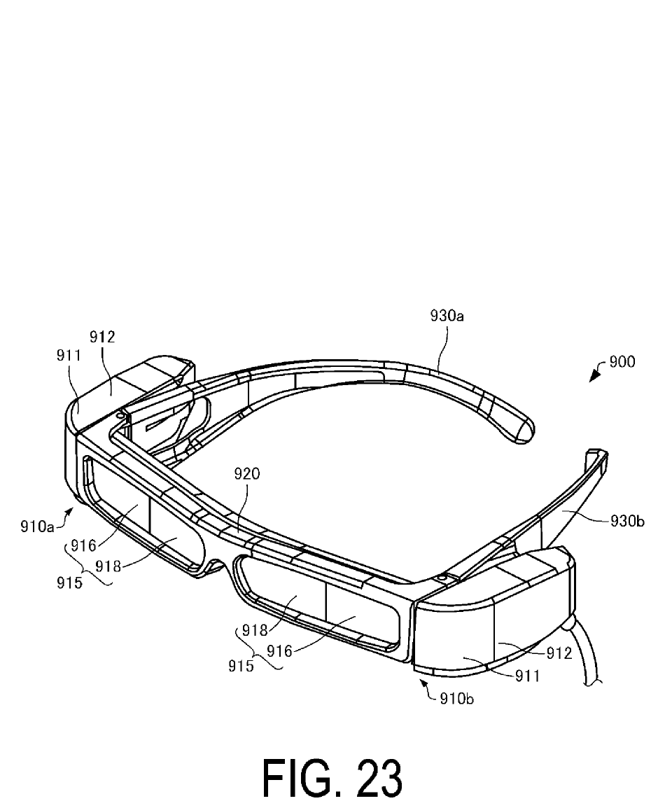

Next, a head-mounted display as an electronic apparatus according to the present embodiment will be described with reference to the drawings. FIG. 23 is a perspective view schematically illustrating a head-mounted display 900 according to the present embodiment.

As illustrated in FIG. 23, the head-mounted display 900 is a head-mounted device that has an outer appearance of an eyewear. The head-mounted display 900 is mounted on the head of a viewer. The viewer is a user who uses the head-mounted display 900. The head-mounted display 900 allows the viewer to visually recognize video light of a virtual image and to visually recognize an external image in a see-through manner.

The head-mounted display 900 includes, for example, a first display unit 910a, a second display unit 910b, a frame 920, a first temple 930a, and a second temple 930b.

The first display unit 910a and the second display unit 910b display images. Specifically, the first display unit 910a displays a virtual image for the right eye of the viewer. The second display unit 910b displays a virtual image for the left eye of the viewer. The display units 910a and 910b include, for example, an image forming device 911 and a light-guiding device 915.

The image forming device 911 generates image light. The image forming device 911 includes, for example, an optical system such as a light source and a projection device, and an external member 912. The external member 912 accommodates the light source and the projection device.

The light-guiding device 915 covers the front of the eyes of the viewer. The light-guiding device 915 guides the video light formed by the image forming device 911 and allows the viewer to visually recognize external light and the video light in an overlapping manner. Details of the image forming device 911 and the light-guiding device 915 will be described below.

The frame 920 supports the first display unit 910a and the second display unit 910b. For example, the frame 920 surrounds the display units 910a and 910b. In the example illustrated in the drawing, the image forming device 911 of the first display unit 910a is attached to one end portion of the frame 920. The image forming device 911 of the second display unit 910b is attached to the other end portion of the frame 920.

The first temple 930a and the second temple 930b extend from the frame 920. In the example illustrated in the drawing, the first temple 930a extends from one end portion of the frame 920. The second temple 930b extends from the other end portion of the frame 920.

The first temple 930a and the second temple 930b are put on the ears of the viewer when the head-mounted display 900 is worn by the viewer. The head of the viewer is positioned between the temples 930a and 930b.

### 6.2. Image Forming Device and Light-guiding Device

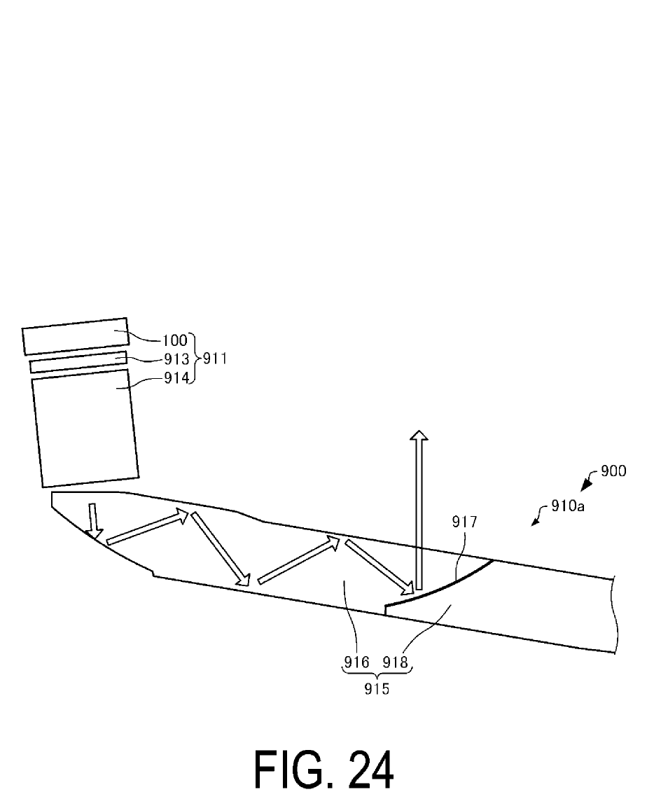

FIG. 24 is a diagram schematically illustrating the image forming device 911 and the light-guiding device 915 of the first display unit 910a of the head-mounted display 900. The first display unit 910a and the second display unit 910b have basically the same configuration. Thus, the following description of the first display unit 910a can be applied to the second display unit 910b.

As illustrated in FIG. 24, the image forming device 911 includes, for example, the light-emitting device 100 as a light source, an optical modulation device 913, and a projection device 914 for image formation.

The optical modulation device 913 modulates the light incident from the light-emitting device 100 based on image information, and emits video light. The optical modulation device 913 is a transmissive liquid crystal light valve. The light-emitting device 100 may be a self-luminous light-emitting device that emits light based on the image information input. In this case, the optical modulation device 913 is not provided.

The projection device 914 projects the video light emitted from the optical modulation device 913 toward the light-guiding device 915. The projection device 914 is, for example, a projection lens. As the lens constituting the projection device 914, a lens having an axially symmetric surface as a lens surface may be used.

The light-guiding device 915 is accurately positioned with respect to the projection device 914, for example, by being screwed to a lens barrel of the projection device 914. The light-guiding device 915 includes, for example, a video light-guiding member 916 that guides the video light and a see-through member 918 for see-through view.

The video light emitted from the projection device 914 is incident on the video light-guiding member 916. The video light-guiding member 916 is a prism that guides the video light toward the eyes of the viewer. The video light incident on the video light-guiding member 916 is repeatedly reflected on the inner surface of the video light-guiding member 916, and is then reflected by a reflective layer 917 to be emitted from the video light-guiding member 916. The video light emitted from the video light-guiding member 916 reaches the eyes of the viewer. The reflective layer 917 is constituted by, for example, a metal or a dielectric multilayer film. The reflective layer 917 may be a half mirror.

The see-through member 918 is adjacent to the video light-guiding member 916. The see-through member 918 is fixed to the video light-guiding member 916. The outer surface of the see-through member 918 is continuous with, for example, the outer surface of the video light-guiding member 916. The viewer sees external light through the see-through member 918. The video light-guiding member 916 also has a function of making the viewer see external light therethrough, in addition to the function of guiding video light. The head-mounted display 900 may be configured not to allow the viewer to see external light therethrough.

The light-emitting devices according to the embodiments described above can be used for devices other than the projector, the display, and the head-mounted display. The light-emitting devices according to the embodiments described above can be used, for example, in indoor and outdoor lighting, laser printers, scanners, sensing devices that use light, electronic view finders (EVFs), wearable displays such as smart watches, in-vehicle lights, in-vehicle heads-up devices, and televisions.

The embodiments and modification examples described above are examples and are not intended as limiting. For example, the embodiments and the modification examples can also be combined together as appropriate.

The present disclosure includes configurations that are substantially the same as the configurations described in the embodiments, for example, configurations with the same functions, methods and results, or with the same advantages and effects. The present disclosure includes configurations obtained by replacing non-essential portions of the configurations described in the embodiments. The present disclosure includes configurations having the same operations and effects or can achieve the same advantages as the configurations described in the embodiments. The present disclosure includes configurations obtained by adding known techniques to the configurations described in the embodiments.

The following content is derived from the embodiments and modification examples described above.

A light-emitting device according to one aspect includes: a first electrode; a second electrode having a light-transmissive property; a first semiconductor layer provided between the first electrode and the second electrode and having a first conductivity type; a second semiconductor layer provided between the first semiconductor layer and the second electrode and having a second conductivity type different from the first conductivity type; a light-emitting layer provided between the first semiconductor layer and the second semiconductor layer; and a reflective layer provided between the first electrode and the first semiconductor layer and configured to reflect and condense light generated in the light-emitting layer toward the second electrode.

According to the light-emitting device, light extraction efficiency can be improved.

In the light-emitting device according to one aspect, a surface of the reflective layer on the first semiconductor layer side may be a concave surface.

According to the light-emitting device, light generated in the light-emitting layer can be reflected and condensed toward the second electrode by the surface of the reflective layer on the first semiconductor layer side.

In the light-emitting device according to one aspect, the light-emitting device may further include a Fresnel lens provided between the reflective layer and the first semiconductor layer.

According to the light-emitting device, a processing time for the lens can be shortened.

In the light-emitting device according to one aspect, the light-emitting device may further include a light-condensing unit provided on a side of the second electrode opposite to the second semiconductor layer and configured to condense the light generated in the light-emitting layer.

According to the light-emitting device, light extraction efficiency can be further improved.

In the light-emitting device according to one aspect, the light-emitting device may further include a metal layer provided at a side of the light-emitting layer and reflecting light generated in the light-emitting layer toward the light-condensing unit.

According to the light-emitting device, light extraction efficiency can be further improved.

In the light-emitting device according to one aspect, the first semiconductor layer, the light-emitting layer, and the second semiconductor layer may constitute a plurality of columnar portions.

According to the light-emitting device, distortion of the light-emitting layer can be reduced.

A display device according to one aspect includes the light-emitting device according to one aspect.

An electronic apparatus according to one aspect includes the light-emitting device according to one aspect.

What is claimed is:

1. A light-emitting device comprising:
a first electrode;
a second electrode having a light-transmissive property;
a first semiconductor layer provided between the first electrode and the second electrode and having a first conductivity type;
a second semiconductor layer provided between the first semiconductor layer and the second electrode and having a second conductivity type different from the first conductivity type;
a light-emitting layer provided between the first semiconductor layer and the second semiconductor layer; and
a reflective layer provided between the first electrode and the first semiconductor layer and configured to reflect and condense light generated in the light-emitting layer toward the second electrode.

2. The light-emitting device according to claim 1, wherein
a surface of the reflective layer on a first semiconductor layer side is a concave surface.

3. The light-emitting device according to claim 1, further comprising
a Fresnel lens provided between the reflective layer and the first semiconductor layer.

4. The light-emitting device according to claim 1, further comprising
a light-condensing unit provided at a side of the second electrode opposite to the second semiconductor layer and configured to condense the light generated in the light-emitting layer.

5. The light-emitting device according to claim 4, further comprising
a metal layer provided at a side of the light-emitting layer and configured to reflect the light generated in the light-emitting layer toward the light-condensing unit.

6. The light-emitting device according to claim 1, wherein
the first semiconductor layer, the light-emitting layer, and the second semiconductor layer constitute a plurality of columnar portions.

7. A display device comprising the light-emitting device according to claim 1.

8. An electronic apparatus comprising the light-emitting device according to claim 1.
